(19) United States
(12) Patent Application Publication
(10) Pub. No.: US 2023/0114948 A1
(43) Pub. Date: Apr. 13, 2023

(54) CONDUCTIVE ADHESIVE-BARRIER ENABLING INTEGRATED PHOTOELECTRODES FOR SOLAR FUELS

(71) Applicant: William Marsh Rice University, Houston, TX (US)

(72) Inventors: Aditya D. Mohite, Houston, TX (US); Michael Wong, Houston, TX (US); Austin Fehr, Houston, TX (US); Ayush Agrawal, Houston, TX (US); Faiz Mandani, Houston, TX (US)

(73) Assignee: William Marsh Rice University, Houston, TX (US)

(21) Appl. No.: 18/045,710

(22) Filed: Oct. 11, 2022

Related U.S. Application Data
(60) Provisional application No. 63/254,788, filed on Oct. 12, 2021.
(60) Provisional application No. 63/254,401, filed on Oct. 11, 2021.

(51) Int. Cl. H01G 9/048; H01G 9/042

(52) U.S. Cl. CPC H01G 9/048; H01G 9/0425; H01G 9/20

(57) ABSTRACT

A multicomponent conductive adhesive barrier includes an adhesive layer and a conductive barrier. The adhesive layer includes a doped pressure-sensitive adhesive and the conductive barrier layer is a carbon or metal-based material. A photoelectrode structure includes a substrate, a photoabsorbing layer, a multicomponent conductive adhesive barrier, and an electrocatalyst. A method for fabricating the photoelectrode structure includes applying a photoabsorbing layer to a substrate, preparing an adhesive layer, and forming a multicomponent conductive adhesive barrier by applying a conductive barrier layer to the adhesive layer.

### CROSS REFERENCE TO RELATED APPLICATIONS

The present Application claims priority to U.S. Provisional Application Nos. 63/254,401 and 63/254,788 which are hereby incorporated by reference in their entirety.

### STATEMENT REGARDING FEDERALLY SPONSORED RESEARCH OR DEVELOPMENT

This invention was made with government support under Grant No. DE-EE0008843 awarded by the United States Department of Energy. The government has certain rights in the invention.

### BACKGROUND

The direct conversion of abundant feedstocks such as water, carbon dioxide, and nitrogen to fuels using only solar energy (“solar fuels”) is one of the most promising ways to achieve reliable and on-demand sustainable clean energy.

To address the global threat of climate change, it is critical to improve the ability to capture and use renewable energy resources like solar energy. Solar energy can only be directly converted into electrical energy, which is inherently difficult to transport and store, and which will continue to limit its widespread adoption. The challenges of transportation, storage, and use for broad energy applications can all be solved by further efficient transformation to chemical energy in the form of “solar fuels,” such as in hydrogen (H₂) bonds, or via electrochemical CO₂ or nitrogen (N₂, NO₃⁻, NO₂⁻) reduction.

Several strategies for sunlight-driven water-splitting to generate green hydrogen (without generating greenhouse gases), which can be stored for long-term use, have been pursued over the past three decades. Conventional integrated photoelectrode (PE)-type devices seek to minimize cost by coupling an efficient photo-absorber with catalysts that facilitate the hydrogen evolution and oxygen evolution reactions. The thermodynamic minimum potential required to split water is 1.23V. However, due to catalytic inefficiencies, real PE systems require up to 1.8V, which has restricted photo-absorbers and photovoltaic devices to those which can deliver a voltage equal to 1.8V.

State-of-the-art PEs and photoelectrochemical cells (PECs) generally use semiconductor based tandem photovoltaic devices with hydrogen and oxygen evolution catalysts, often operating under concentrated sunlight to achieve solar-to-hydrogen (STH) efficiencies exceeding 19% with hours of continuous operation for a device with up to 0.3 cm² active area. However, despite their high STH efficiency, III-V based PEC platforms are cost prohibitive.

As a result, halide perovskites have emerged as low-cost solution-processed semiconductors, exhibiting near-ideal properties such as direct and tunable bandgaps, large absorption coefficients, long diffusion lengths, and long charge carrier lifetimes which have enabled high-efficiency photovoltaic devices with efficiencies exceeding 25%. Importantly, two halide perovskite photovoltaic devices can be combined in series to produce an operating voltage of 1.8V with a high current density>20 mA/cm² at the maximum power point to efficiently drive unassisted solar water splitting.

One of the most serious challenges in realizing an integrated halide perovskite photoelectrode (HaP-PE), in which at least one interface is in direct contact with the electrolyte, is the spontaneous dissolution of halide perovskites in aqueous media due to their ionic character.

Existing barrier technologies and photoelectrode designs are not widely applicable to arbitrary photoabsorbers or to arbitrary reactions. They are also universally assembled in a bottom-up fashion with successive layers deposited on a single stack. The conventional approach to photoelectrode designs does not outline specific layers or design constraints, and often has fewer layers with unnecessary or heightened design constraints (e.g. nm-scale layers of catalyst which also acts as a barrier and are chemically adhered to the photoabsorber —an “all-in-one” type solution). No barrier technology has resulted in an effective photoelectrode using halide perovskite photoabsorbers.

### SUMMARY

The present disclosure relates to a multicomponent conductive adhesive barrier for a photoelectrode structure, a photoelectrode structure including the multicomponent conductive adhesive barrier, and a photoelectrochemical cell (“PEC”) including the photoelectrode structure.

### BRIEF DESCRIPTION OF THE DRAWINGS

FIG. 1A is a schematic of a p-i-n perovskite solar cell in accordance with one or more embodiments.

FIG. 1B is a cross-sectional scanning electron microscopy image of a CAB in accordance with one or more embodiments.

FIG. 2 is a schematic of a process of making a PEC device in accordance with one or more embodiments.

FIGS. 3A and 3B show the J-V curves for p-i-n and n-i-p solar cells, respectively, in accordance with one or more embodiments.

FIG. 3C shows external quantum efficiency for a p-i-n solar cell in accordance with one or more embodiments.

FIGS. 4A-4C are J-V curves of perovskite solar cells in accordance with one or more embodiments.

FIG. 5A shows J-V curves of a photocathode and electrocatalyst in accordance with one or more embodiments.

FIG. 5B shows an image of the photocathode device used to collect the data of FIG. 5A.

FIG. 5C shows J-V curves of a photoanode and electrocatalyst in accordance with one or more embodiments.

FIG. 5D shows an image of the photoanode device used to collect the data of FIG. 5C.

FIG. 6 is a schematic of a perovskite solar cell in accordance with one or more embodiments.

FIG. 7A shows J-V curves for solar cells in accordance with one or more embodiments.

FIG. 7B shows the photoconversion efficiency for solar cells in accordance with one or more embodiments.

FIG. 8A shows J-V curves of a photocathode and electrocatalyst in accordance with one or more embodiments.

FIG. 8B shows J-V curves of a photoanode and electrocatalyst in accordance with one or more embodiments.

FIG. 9A is a schematic of an integrated HaP-PE in accordance with one or more embodiments.

FIG. 9B shows the time-dependent current density for bias-free water-splitting for the integrated HaP-PE of FIG. 9A.

FIG. 9C shows individual photoelectrode J-V curves of the integrated HaP-PE of FIG. 9A.

FIG. 10A shows a silicon-perovskite photoanode J-V curve under 1-Sun illumination in accordance with one or more embodiments.

FIG. 10B is photographs of a silicon-perovskite photoanode in accordance with one or more embodiments.

FIG. 10C is a wet photoanode J-V curve under 1-Sun illumination in 0.5M H₂SO₄ in accordance with one or more embodiments.

FIG. 10D shows unassisted water-splitting photocurrent of silicon-perovskite photoanode in accordance with one or more embodiments.

FIG. 11 is a comparison of devices in accordance with the present disclosure to state-of-the-art devices.

FIG. 12A shows an activity of a model oxidation electrocatalyst in accordance with one or more embodiments.

FIG. 12B shows the temperature of an integrated photoelectrode as a function of time in accordance with one or more embodiments.

FIG. 12C shows J-V curves for a photoanode consisting of a silicon-perovskite and an IrOₓ, electrocatalyst in accordance with one or more embodiments.

### DETAILED DESCRIPTION

Specific embodiments will now be described in detail with reference to the accompanying figures. Like elements in the various figures are denoted by like reference numerals for consistency. In the following detailed description of embodiments, numerous specific details are set forth in order to provide a more thorough understanding.

However, it will be apparent to one of ordinary skill in the art that embodiments may be practiced without these specific details. In other instances, well-known features have not been described in detail to avoid unnecessarily complicating the description.

In the following description, any component described with regard to a figure, in various embodiments of the present disclosure, may be equivalent to one or more like-named components described with regard to any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements, if an ordering exists.

One or more embodiments relate to a multicomponent conductive barrier layer for a photoelectrode structure, a photoelectrode structure including the multicomponent conductive barrier layer, and a PEC including the photoelectrode structure, as described in further detail below.

One or more embodiments provided herein relate to devices, systems, and methods for a photoelectrochemical cell (PEC) comprising a multicomponent conductive barrier layer, to achieve unassisted solar water-splitting to produce green hydrogen. In one or more embodiments, the photoelectrochemical cells may include a multicomponent conductive adhesive barrier (CAB) for photoelectrode devices designed with high-efficiency and technologically relevant stability. Furthermore, when incorporated into an integrated photoelectrode (I-PEC), the CAB described herein may also be useful for harvesting wasted heat and transmitted light in photoelectrodes.

An enabling technology for building an integrated HaP-PE, according to one or more embodiments provided herein, entails the design and development of a multicomponent conductive adhesive barrier which protects the HaP from the corrosive electrolytes without compromising electronic transport of photogenerated electrons and holes from the perovskite to the catalyst deposited on the barrier layer. Historically, efforts to fabricate protective and conductive barriers have employed different strategies. Although these demonstrations preserved the short-circuit current density of the parent photovoltaics in some cases, they introduced significant series resistance, reducing the fill factor and the operating voltage at the maximum power point, hindering their capacity for bias-free operation. As a result, the state-of-the-art STH efficiency for an integrated halide perovskite PEC system has been limited to 6% with <20 min of continuous operation.

To address the instability of conventional photoelectrodes, devices incorporating barriers between the photoabsorber and the catalyst that protect the photoabsorber from the electrolyte are proposed herein. The benefits of the device design are achieved through the identification of two distinct design components in the adhesive and barrier layers, where the identification of their respective design criteria, and the demonstration of state-of-the-art device performance are realized when these criteria are satisfied. Additionally, as detailed in one or more embodiments of the present disclosure, an Ag-doped adhesive CAB fabrication process is decoupled from the photoabsorber fabrication process and allows for the fabrication of the adhesive-barrier stack, including any necessary curing or outgassing, separately from the photoabsorber before attachment.

The devices, systems, and methods of one or more embodiments herein may employ an integrated HaP-PE device with an STH of greater than 12% with continuous bias-free operation using a novel design in which photocathode and photoanodes are laterally separated and connected in series using low-resistance metallic connections including ITO, FTO, conductive tapes such as with Cu or graphite, metallic wires using Cu, Al, or Ag, or alloys used for electrically conductive soldered connections. The devices, systems, and methods of one or more embodiments herein may also employ a multijunction tandem photovoltaic device stack (for e. g. Si/perovskite, perovskite-perovskite or III-V group) integrated PE device with an STH of greater than 20% with continuous bias-free operation in which the photoelectrode is coupled with a wired counter electrode in series. The design decouples the device interfaces for light absorption and catalysis, which respectively occur through optically transparent ITO and on deposited catalysts immersed in electrolyte.

Accordingly, in one or more embodiments, the water-soluble HaP photovoltaic devices may be protected with a multi-component bilayer barrier technology, referred to herein as a multicomponent conductive adhesive barrier, or as CAB, which is composed of a sheet of conductive, inert, and impermeable material and a conductive adhesive. For example, in one or more embodiments, the composite CAB may be comprised of materials including, but not limited to, graphite, titanium, copper, nickel, and stainless steel, which may be attached to the solar cell electrode using an adhesive conductive ink. In one or more embodiments, the adhesive conductive ink may be formulated with a polymer and particulate conductors, such as metals (e.g., Ag, Cu) and carbon-based conductors, as fillers.

As detailed herein, measurements performed on individual fabricated photocathodes and photoanodes, prepared with Pt and IrO₂ catalysts deposited on the barrier, demonstrated near-perfect translation of the photovoltaic efficiency to the catalytic reaction with stability in a three-terminal measurement under continuous operation. Additionally, the potential for scalability is demonstrated using a Si/perovskite tandem integrated photoanode with 1 cm² active area with 100 hours of unassisted water splitting operation under continuous illumination is provided herein. The HaP-PE platform of one or more embodiments is generally applicable for driving any arbitrary reactions and paves a path for developing a low-cost technology for solar-to-fuel conversion.

The multicomponent barrier for the photoelectrode structure according to one or more embodiments of the present disclosure includes the photoelectrode structure which includes a photoabsorber, and a multicomponent barrier adhesive layer which includes an adhesive layer, a conductive barrier layer, and an electrocatalyst which may be deposited onto the conductive barrier layer. The adhesive layer may comprise a material which acts through physical adhesion to create a low resistance contact between the solar cell and barrier. The barrier protective layer may comprise a material which prevents transport of electrolyte species, such as water, from the electrolyte to the lower layers includes the adhesive and the photoabsorber. The water impermeability may result from a dense structure of the material of the barrier protective layer. By having such a structure, the multicomponent barrier effectively mitigates corrosion from occurring by protecting a photoabsorbing layer of the photoelectrode structure from directly contacting electrolyte species.

The device, including the multicomponent barrier layer, may be fabricated linearly, from the photoabsorber to the electrocatalyst, or in parallel, where the photoabrosber/solar cell and the multicomponent barrier including the adhesive, barrier, and electocatalyst components are separately fabricated before connecting them in a final step. Regardless of the type of the light absorbing layer of the photoelectrode structure, the multi-component barrier may protect the photoelectrode structure in various external environments. In one or more embodiments, the adhesive component of the multicomponent barrier may be either drop- or spin-coated onto either the photoabsorber or barrier. The catalyst can be deposited onto the barrier either before or after connecting the barrier and the adhesive, depending on process needs.

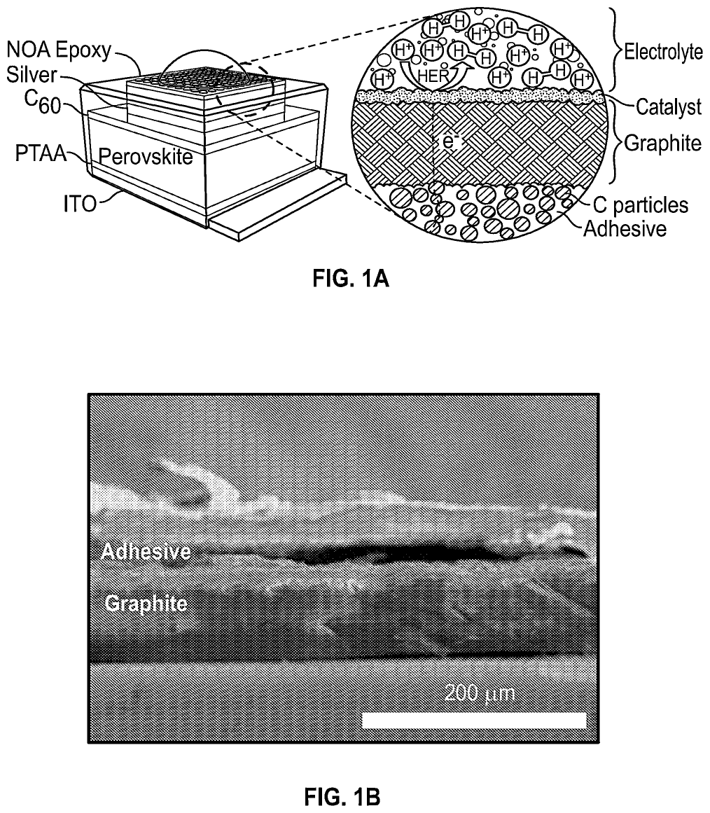

In one or more embodiments, the multicomponent barrier, also referred to as the CAB, which is conductive, impermeable, and inert with respect to electrolytes, can be adhered to a photoabsorber/solar surface with minimal contact resistance. A schematic of an exemplary photoelectrode including the CAB is illustrated in FIG. 1A. The architecture shown in FIG. 1A includes a p-i-n perovskite solar cell (ITO|PTAA|perovskite|C₆₀| Ag), a CAB (conductive C-bearing adhesive|graphite), and a catalyst on the surface. The non-active area is encapsulated in an inert and non-conductive epoxy. A cross-sectional scanning electron microscopy (SEM) image showing layers of the same is shown in FIG. 1B. The SEM image is an upside-down CAB with conductive adhesive on top and graphite on the bottom. In one or more embodiments, a typical photoelectrode stack may include a photoabsorber or solar cell, a multicomponent CAB, and a catalyst stacked in that order. Inclusion of the multicomponent CAB layer is a design approach which can be implemented with many materials so long as they fit the design criteria, is compatible with arbitrary photoabsorbers, and can work on electrochemical reactions including both reduction/cathode and oxidation/anode reactions. Additionally, the respective components of the PEC, including the multicomponent CAB layer, can be assembled independently, and replaced, which enables a transformational opportunity for enhancing photoelectrode device lifetime while retaining efficiency.

In other embodiments, the multicomponent CAB may be incorporated into an integrated photoelectrode (I-PEC) for the purposes of reducing waste heat. The required overpotential to drive an electrolyzer at a particular current density is a function of the local temperature. However, the use of a supplemental heating source increases the system's external energy requirement and counteracts the potential financials savings associated with increased electrocatalyst activity. Multicomponent CAB-enabled I-PECs in accordance with one or more embodiments are capable of harvesting waste heat from light that is not harvested into the semiconductor, thereby increasing the electrocatalyst local temperature without increasing the systems energy demand.

As detailed herein, the development of a multicomponent CAB-based photoelectrode for the cathodic hydrogen evolution reaction (HER) and anodic oxygen evolution reaction (OER) is demonstrated along with their combined operation together to achieve unassisted water-splitting to produce green hydrogen.

Furthermore, embodiments described herein detail using the same multicomponent CAB in an I-PEC to enable harvesting of waste heat in electrolyzers. Spatially and electronically integrating the photovoltaic and the electrocatalyst via a catalyst coated CAB enables heating the electrocatalyst via photovoltaic waste heat from unused light. Even ideal photovoltaics are unable to fully utilize the full solar spectrum. High energy hot carriers are unable to be extracted and generate heat as they relax to their ground state and low energy photons (below the bandgap of the photo absorber) are transmitted through the photovoltaic stack. The CAB of the present disclosure may serve a dual purpose to increase the local temperature of the electrocatalyst: First, it is an excellent thermal conductor and favors heat transfer from the photovoltaic to the electrocatalyst. Second, it is a near perfect blackbody and low energy photons transmitted through the photovoltaic stack are converted to heat.

Photoabsorber

In one or more embodiments, the PE may include a photoabsorber which may be a semiconductor or solar cell device, including, but not limited to, silicon, III-V, and halide perovskites. The photoabsorber may have a metallic termination for charge collection as the adhesive cannot efficiently harvest charges directly from a semiconductor. The material selected may have a high solar-to-electric energy conversion efficiency and stability when operated as a photovoltaic. In one or more the embodiments, the modular design of the CAB comprising photoelectrode device enables the use of any photoabsorber material such as Si or III-V, as long as the photoabsorber has a conductive metallic surface termination to be adhered to the multicomponent conductive adhesive barrier to conduct the electrochemical reaction. Due to the extremely low electronic resistance, charge carriers are efficiently transferred from the photoabsorber to the catalyst surface.

Conductive Adhesive

In one or more the embodiments, the multicomponent barrier, or CAB, may include an adhesive component that operates through physical adhesion, where the function of the adhesive layer is to create a low-resistance contact between the solar cell and barrier which does not degrade the adjacent layer on its own during deposition (ie. via heat, outgassing, etc.) or under electrical bias (operating conditions).

This layer may be engineered to provide sticker-like peel-on/peel-off or replaceability features. Specifically, this layer may be tailored via control of dopant concentration, thickness of adhesive, and the exact chemistry/synthesis can be tuned to affect the peel/tack/residue-leaving properties of the adhesive. This feature of replaceability is one pathway to enhanced stability.

For example, in one or more embodiments, the conductive adhesive layer component may comprise a doped pressure-sensitive adhesive (PSA). The PSA of the present disclosure may be selected from those commonly known in the art. For example, the PSA may be a tacky pressure-sensitive adhesive composition comprising a polymerized acrylic or methacrylic acid ester backbone having grafted pendant polymeric moieties.

In one or more embodiments, the conductive adhesive layer may be selected from one or more of an Ag-doped pressure-sensitive adhesive, C-doped pressure-sensitive adhesive, Cu-doped pressure-sensitive adhesive, commercial 2-sided conductive tape, such as 3M's Electrically Conductive Adhesive Transfer Tape 9711S, but a number of materials are possible. For example, embodiments may include other conducting dopants, such as, but not limited to Ti, and Au and/or modifications to the polymer chain where different molecular weights or different extents of branching from the same precursors may be included. Additionally, in some embodiments, different precursors may be used including, but not limited to, isooctyl acrylate to isoamyl acrylate. However, one skilled in the art would appreciate that there are number of possible precursor materials that would meet the present design criteria, which may be tailored to fit the needs of the produced device and/or system. The adhesive layer may have a resistance of less than 1 ohm cm⁻². In one or more embodiments, the adhesive layer may be doped with Ag nanoparticles or carbon black.

A thickness of the conductive adhesive layer may be about 0.1, 1.0, 10, and 100 micrometer (μm) to about 1, 10, 100, 500, and 1000 where in lower limit may be combined with any mathematically feasible upper limit.

Other embodiments, the conductive adhesive layer may include conducting dopants such as Ti or Au. Additionally, the conductive adhesive layer may comprise slight modifications to the polymer chain (different molecular weights or different extents of branching from the same precursors, or different precursors such as isooctyl acrylate to isoamyl acrylate, but there are dozens or hundreds or more of possible precursor materials that would meet our design criteria.

Conductive Barrier

In one or more the embodiments, the multicomponent barrier may include a conductive barrier material which prevents transport of electrolyte species, such as water, from the electrolyte to the lower layers of the device, such as the adhesive or photoabsorber.

In one or more embodiments, the conductive barrier layer should have very low electrical resistance that is less than 1 ohm cm⁻². Furthermore, the conductive barrier layer should generally be minimally reactive with the electrolyte and catalysts, which are highly dependent on the reaction, under bias.

In one or more embodiments, the conductive barrier may be comprised of one selected from a metal, carbon-based material of a degenerately doped semiconductor. The metal includes at least one metal selected from Group 5, Group 11, and Group 13, an alloy thereof, and stainless steel, Non-limiting examples of the metal include nickel (Ni), aluminum (Al), copper (Cu), tantalum (Ta), niobium (Nb), and titanium (Ti), an alloy thereof, and stainless steel.

The carbon-based material includes at least one selected from amorphous carbon, pyrolytic graphite, and grapheme.

In one or more embodiments, the conductive barrier may be comprised of electronically metallic sheets or “foil”, such as Ti foil, pyrolytic graphite, Cu foil, and Ni foil, or combinations thereof.

A thickness of the conductive barrier layer may be about 0.1, 1.0, 10, and 100 micrometer (μm) to about 1, 10, 100, 500, and 1000 where in lower limit may be combined with any mathematically feasible upper limit.

Electrocatalyst

In one or more the embodiments, the photoelectrode stack may include an electrocatalyst which may be any catalyst that can be deposited on the conductive barrier material. As a feature of this device design, the electrocatalyst catalyst can be deposited on the barrier before the barrier is adhered to the photoabsorber.

In one or more embodiments, the electrocatalyst may include, but is not limited to, at least one selected from copper (Cu), platinum (Pt), iridium (Jr), palladium (Pd), ruthenium (Ru), rhodium (Rh), iridium oxide (IrO₂), nickel molybdenum (NiMo), nickel molybdenum nitride (NiMoNₓ , 0.1≤x≤2) nickel molybdenum zinc (NiMoZn), molybdenum sulfide (MoS₂ or Mo₃S₄), cobalt-phosphate (Co-Pi oxygen evolution catalyst), cobalt oxide (CO₃O₄), cobalt phosphorus (CoP), ruthenium oxide (RuO₂) and rhodium oxide (Rh₂O₃).

In one or more embodiments, the electrocatalyst may be, but is not limited to, one or more of sputtered and/or ink-deposited Pt, Jr, IrO₂, and Cu.

In one or more embodiments, when the photoelectrode structure is a photocathode, the electrocatalyst may include Pt, NiMo, NiMoZn, MoS₂, or Mo₃S₄ suitable for the proton reduction.

In one or more embodiments, when the photoelectrode structure is a photoanode, a catalyst, e.g., Ir, ITO₂, Ru, RuO₂, Co₃O₄, or Co-Pi, suitable for oxidizing water may be used for the electrocatalyst.

As briefly discussed, existing technologies like commercial conductive inks and thick metal alloys are limited in terms of catalyst processing temperature or fluid removal during deposition. The presently disclosed device design allows for the decoupling and parallel processing of the CAB-catalyst and the solar cell fabrication. This enables facile use of an array of potential catalyst deposition techniques like sputtering, inks of catalyst nanoparticles and single atom catalysts that may require high temperature annealing, and other reactive deposition steps that are prohibited by photovoltaic, adhesive, and or barrier stability.

Methods for Fabricating Adhesive Component

In one or more the embodiments, the multicomponent conductive barrier may include an adhesive layer comprising a doped pressure sensitive adhesive. The pressure-sensitive adhesive may be both electrically conductive and can bind two planar surfaces without outgassing, and a pressure-sensitive adhesive doped with conductive fillers may be prepared and/or obtained. For example, the pressure sensitive adhesive (PSA) may be synthesized via copolymerization of a set of compatible monomers according to classical methods, known in the art.

Methods for preparing the doped PSA may generally include a first step where the following species are added to a reactor under an inert atmosphere: ethyl acetate, isooctyl acrylate, methacrylic acid, benzoyl peroxide. As the copolymer forms via free radical chain polymerization, it is significant that the atmosphere is free of oxygen, a known radical scavenger. Presence of such impurities can prematurely quench the reaction and lead to a significant decrease in average molecular weight of the copolymer and reduced viscosity. The reaction vessel is maintained at about 50° C. and stirred continuously. After a noticeable increase in solution viscosity, ethyl acetate, methacrylic acid, and benzoyl peroxide are added to the reaction vessel. After about 10 h, the reaction is complete, and the product is diluted to a desired viscosity in an organic solvent (between 1-100 g solvent added per 1 g of polymer product). The synthesized PSA may be provided with conductive properties via addition of silver nanoparticles or Cu nanoparticles or carbon black (CB) at concentrations beyond the percolation concentration (ex. 0.2 g/g filler/PSA). Note that the tack and shear properties can be varied via use of varied solvents for the reaction or manipulation of the relative ratios of the components. Furthermore, the chemistry presented above is one of many that are potential candidates for this application.

The modular device design of the disclosed CAB-based photoelectrode enables parallel processing, improved manufacturability, and a larger phase space of catalyst and adhesive materials than in the conventional bottom-up linear fabrication of photoelectrodes in which the stability of all deposited layers limits successive layers.

In one or more embodiments, the multicomponent conductive adhesive barrier, or CAB, can be mixed-and-matched with a variety of photoabsorbers and a variety of catalysts for a variety of reactions. For example, in some embodiments, highly conductive metallic barriers such as thick Ti, Cu, Ni foil and pyrolytic or other graphite materials, with high conductivity and low permeability, can be used with Ag, Cu, or C doped PSA or 3M conductive tapes, allowing the adhesive and/or catalyst to be deposited separately before being adhered to the photoabsorber layer.

For example, in one or more embodiments, a photoelectrode maybe fabricated by applying a photoabsorber to a substrate, preparing an adhesive layer and forming a multicomponent adhesive barrier layer by applying a conductive barrier layer to the adhesive layer. In some embodiments, the multicomponent conductive adhesive barrier may be formed before applying the adhesive layer, and the attached conductive barrier layer, to the to the photoabsorbing layer. In other embodiments, the multicomponent conductive adhesive barrier may be formed after applying the adhesive layer to the to the photoabsorbing layer.

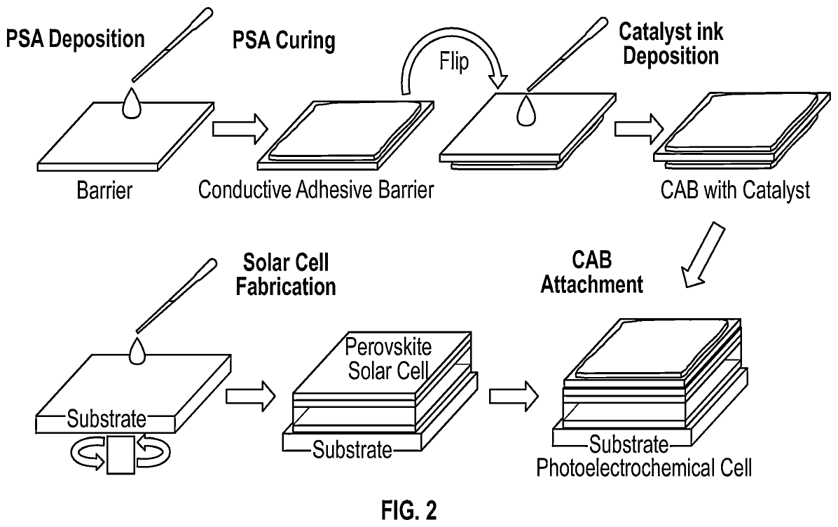

A schematic of an exemplary process is shown in FIG. 2. In the embodiment shown in FIG. 2, conductive adhesive is deposited on conductive barrier, then barrier is flipped and catalyst is deposited on the opposite side. The order of the steps shown in FIG. 2 could be modified, enabling high freedom in terms of fabrication conditions (e.g., temperature, solvent, etc.). Solar cell fabrication occurs entirely in parallel, and adhesive enables attachment of the complete CAB to the complete photovoltaic.

In one or more embodiments, the multicomponent conductive adhesive barrier or the multicomponent conductive adhesive barrier-catalyst can be deposited as a peeled-on sticker, and also removed and replaced with engineering of the peel and tack properties of the adhesive, without damaging the photoabsorber. Additionally, the lack of outgassing in the disclosed adhesives provides the capability for fabrication of photoelectrodes on solvent-sensitive photoabsorbers like halide perovskite solar cells without causing damage during fabrication.

In one or more the embodiments, the photoelectrode device design, containing a multicomponent conductive adhesive barrier can preserve>99% of the efficiency of a solar cell on which it is deposited. When tested as a photoelectrode, the difference from the solar cell photoconversion efficiency (PCE) and the photoelectrode HCE is strictly affected by the overpotential of the electrocatalyst used.

In one or more the embodiments, the design compatibility requirements for the multicomponent conductive adhesive barrier are not limited and can be satisfied by an array of diverse materials including various non-degassing conducting adhesives, single or multi-material barriers, etc. The design constraints of the multicomponent conductive adhesive barrier layers also leave substantial room for additional constraints to be added to grant other functionalities for tailoring of the multicomponent conductive adhesive barrier. The framework also provides the tools necessary to combine layers intelligently.

This multicomponent conductive adhesive barrier design can be used to power any electrochemical reaction if the photoabsorbers selected can provide the necessary voltage and current required to drive the reaction to generate the required product. Examples of alternative reactions include CO₂ reduction to CO and higher carbon molecules, wastewater NO₃⁻ conversion to NH₃ and N₂, and selective partial oxidation of alkanes to CO and higher C molecules.

Conventional photoelectrochemical devices are uniformly assembled in the following order: photoabsorber-adhesive/barrier-catalyst. However, as noted above, this order introduces constraints on the allowable methods for material deposition. For example, in catalysis a common method for synthesizing efficient catalysts is to deposit precursor salts and bake them under controlled atmospheres (e.g. H₂, O₂, or N₂) at high temperature. However, many photoabsorbers degrade at high temperatures, meaning that a photoelectrode assembled in the standard way cannot readily possess any catalyst produced by baking/calcining. Conversely, in the present methods and systems, it is possible to complete assembly in the conventional, linear way as well as either of the following orders: barrier-catalyst-adhesive-photoabsorber or barrier-adhesive-catalyst-photoabsorber.

In one or more the embodiments, the properties of the adhesive layer can be tuned such that the multicomponent conductive adhesive barrier-catalyst layer can be peeled off of the photoabsorber, and a degraded photovoltaic or degraded barrier/catalyst combination can be replaced with a functional one. Thus, in some embodiments, the multicomponent conductive adhesive barrier-catalyst layers act effectively as peelable stickers which can be replaced or transferred to fresh photoabsorbers. This modularity provides for a system where any mismatch between the intrinsic stability of the photoabsorber and the stability of the barrier-catalyst exposed to electrolyte can be offset on the basis of cost by replacing either component. This modular concept also enables sustainable use of materials where the degraded layers can either be regenerated (in catalysts) or safely disposed (in photovoltaics) or recycled. This is a concept that has never been shown in the field of integrated photoelectrodes but which is enabled using the presently disclosed design.

In one or more the embodiments, the general photoelectrode design can be scaled to large area photoelectrodes, so long as there are no significant internal performance losses with a large area photoabsorber. This issue can be resolved with proper material selection and fabrication methods. For example, as shown in the present disclosure, even with a 10× larger area photoabsorber, the photoelectrochemical device performance can be retained at >95% after the application of the Ag-doped PSA-pyrolytic graphite CAB. Therefore, scaling this technology in terms of performance for an active geometric area is only a function of the efficiency of the photoabsorber or solar cell that is used and not dependent on the multicomponent CAB layer

In one or more embodiments, the efficiency of a photoelectrode or PCE including the multicomponent CAB layer is limited by the efficiency of the solar cell and the overpotential of the catalyst exclusively. Greater than 99% of the original photovoltaic's power conversion efficiency is conserved after applying the CAB when tested as a photovoltaic, and when tested as a photoelectrode the only significant losses are due to catalyst overpotential. A high 13.4% solar-to-hydrogen (STH) efficiency is achieved herein, as calculated in Formula 1, with up to 20% half-cell efficiency (HCE), as calculated in Formula 2, for single photoelectrodes with a highly efficient catalyst.

$$STH [ \% ] = \frac{I [ mA ] ⨯ 1.23 [ V ] ⨯ {η}_{f}}{{P}_{s unlight} [ mW ]} \qquad [ Formula 1 ]$$

Where I is the operating current passing through the device, 1.23V is the energy per charge stored in H₂ molecules, ηF is the Faradaic efficiency to H₂ (selectivity of current going to hydrogen evolution or HER), and P_{sunlight} is the total solar power incident on the photoabsorber areas.

$$HCE [ \% ] = \frac{\vert J \vert [ \frac{mA}{{cm}^{2}} ] ⨯ ( V [ V ] - {V}_{0} [ V ] )}{{P}_{sunlight} [ \frac{mW}{{cm}^{2}} ]} \qquad ( Formula 2 )$$

Where J is the absolute current density from the catalyst assuming an area match with the photoabsorber, V is any potential anodic (for a reduction reaction) or cathodic (for an oxidation reaction) to the standard potential of the half-reaction, V₀ is the standard reduction potential of the half-reaction, and P_{sunlight} is the power density delivered to the photoabsorber.

### Examples

Initially, to demonstrate the use of the multicomponent conductive barrier used in photoelectrodes to drive the bias-free water-splitting reaction, planar perovskite solar cells were fabricated in both p-i-n and n-i-p (also known as inverted and regular, respectively) architectures as precursors to the photocathode and photoanode, respectively. FIGS. 1A and 1B of Exhibit B illustrates a general solar cell stack used.

First, pre-etched ITO substrates were acquired. The substrates were washed with soap and DI water and then sonicated for 15 mins each in DI water, Acetone, and Acetone+Ethanol. The chips were dried in Ar flow, and then UV treated for 30 mins before spinning the transport layer.

Architecture p-i-n ITO/PTAA/Cs_{0.05}FA_{0.85}MA_{0.1}Pb(I_{0.95} Br_{0.05})₃/LiF/C₆₀/BCP/Ag

For the p-i-n perovskite devices, the device structure was ITO/PTAA/Cs_{0.05}FA_{0.85}MA_{0.1}Pb(I_{0.95} Br_{0.05})₃/LiF/C₆₀/BCP/Ag (1). The glass/ITO substrates were treated with UV ozone for 15 min before use. The hole transport layer of PTAA was made by spin-coating a 1.5 mg/mL toluene solution at 5000 RPM for 30 s, and then annealed at 100° C. for 10 min. The perovskite films were fabricated by anti-solvent approach in a N₂ glovebox. The perovskite precursor (1.5 M) was prepared by mixing CsI, FAI, MABr, PbBr₂, PbI₂ chemicals in a stoichiometric ratio, and dissolved in mixed solvent of DMF: DMSO (4:1 v/v). The two-step spin-coating procedure with 1000 RPM for 10 s and 4000 RPM for 40 s was used. 150 μL chlorobenzene was dropped onto the spinning substrates during the 20 s of the second spin-coating step, followed by 100° C. annealing for 10 min. Finally, C₆₀ (30 nm), BCP (6 nm) and Ag (100 nm) in sequential order were thermally evaporated under high vacuum.

Architecture n-i-p: FTO/SnO₂/(FAPbI₃)_{0.97}(MAPbI₃)_{0.03}/Spiro-OMeTAD/Au

The n-i-p PSCs was fabricated with the device architecture FTO/SnO₂/(FAPbI₃)_{0.97}(MAPbI₃)_{0.03}/Spiro-OMeTAD/Au. The SnO₂ layer deposited on FTO using the chemical bath deposition (CBD) method (2). After SnO₂/FTO substrates were treated with UV-ozone for 15 min, perovskite precursor was spin-coated on substrate at 500 rpm 10 s, 1000 rpm for 10 s and 5000 rpm 15 s, and 1 mL of ethyl ether was dripped onto the substate being spined. The perovskite layer was annealed at 150° C. for 15 min in an ambient environment. The perovskite precursor was prepared by mixing 1.55 M of FAI, 1.55 M of PbI₂ and 0.05 M of MAPbBr₃ with 35 mol % of methylammonium hydrochloride in a mixed solvent of DMF and DMSO (8:1 v/v). The spiro-OMeTAD solution was spin-coated at 4000 rpm for 20 s. The spiro-OMeTAD solution was prepared by mixing 90 mg/mL of spiro-OMeTAD in chlorobenzene with 23 μL of lithium bis(trifluoro-methanesulfonyl) imide salt (540 mg/ml in acetonitrile), 10 μL of FK209 salt (375 mg/mL in acetonitrile) and 39 μL of 4-tert-butylpyridine. Finally, 100 nm thick gold electrode was deposited by thermal evaporation.

The respective planar perovskite solar cells were characterized as follows. As noted, the p-i-n solar cell was formed with a structure of ITO/PTAA/Cs_{0.05}FA_{0.85}MA_{0.1}Pb(I_{0.95} Br_{0.05})₃/LiF/C₆₀/BCP/Ag such that the photogenerated electrons were transported to the Ag electrode and the holes were collected by ITO. The n-i-p stack was formed with a structure of FTO/SnO₂/(FAPbI₃)_{0.97}(MAPbI₃)_{0.03}/Spiro-OMeTAD/Au such that the photogenerated holes arrive at the Au electrode and the electrons are collected by the FTO.

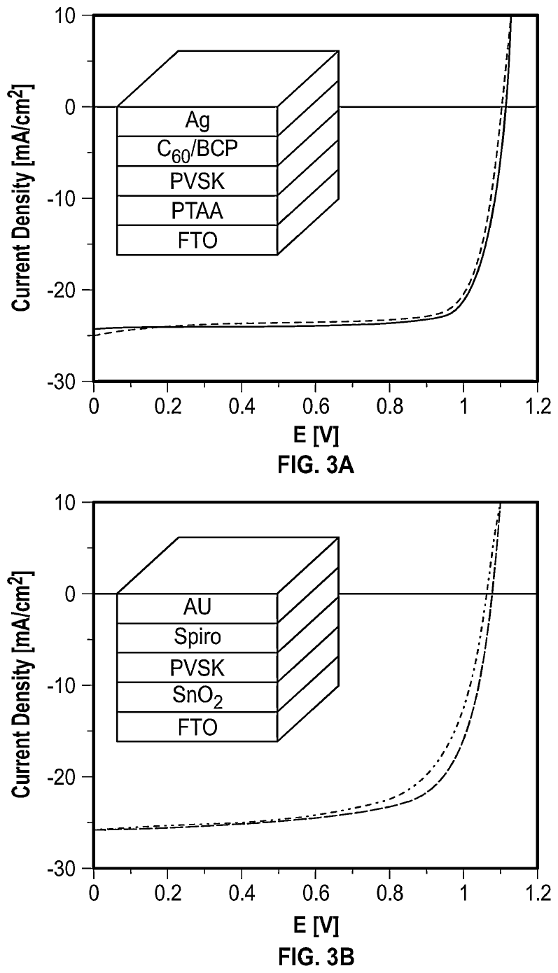

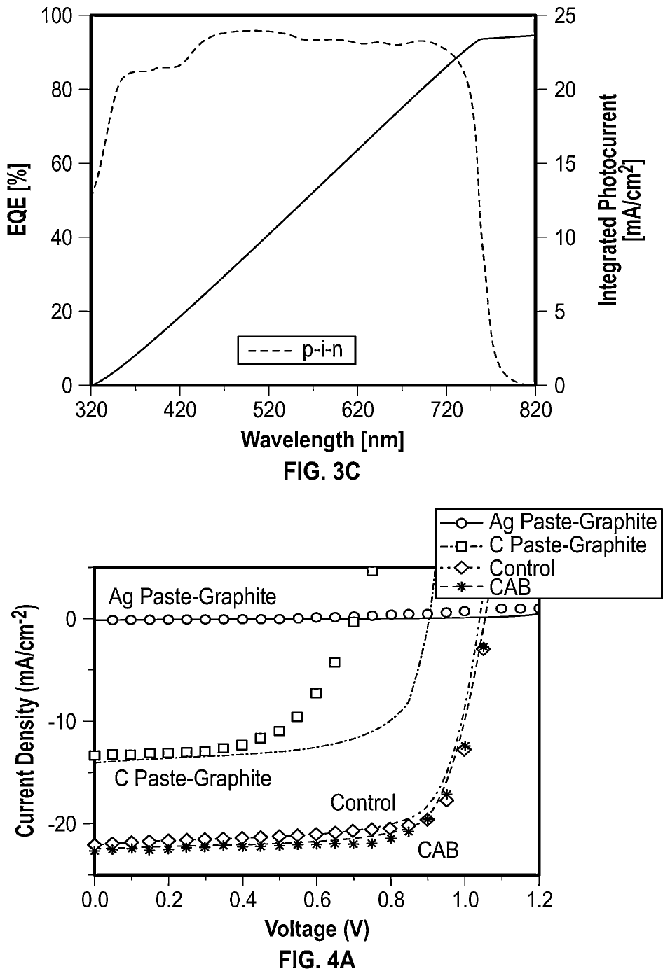

FIGS. 3A and 3B show the current density-voltage (J-V) curves for both the p-i-n and n-i-p solar cells under simulated AM1.5 G solar irradiation (100 mW/cm²). A power conversion efficiency (PCE) of 19.1% was measured with short-circuit current of 22.8 mA/cm², open-circuit voltage of 1.10V and Fill Factor of 0.76 from the champion p-i-n cells with the operating voltage of 0.9V at the maximum power point (MPP). The n-i-p cells yielded a PCE of 20.9% with short-circuit current of 24.4 mA/cm², open-circuit voltage of 1.13V and Fill Factor of 0.76 with an operating voltage of 0.9V at MPP.

FIG. 3C shows the external quantum efficiency for the two cells, which matches well with the bandgap of the corresponding perovskites. The integrated photocurrent density of the p-i-n was measured to be 22.5 mA/cm² of the n-i-p was measured to be 23.6 mA/cm², which was within 5% of the short circuit current density obtained from the J-V curves in FIGS. 3A and 3B, arising from a slight spectral mismatch. The stability of the p-i-n and n-i-p solar cells was measured under AM 1.5 G illumination using MPP tracking (L1 protocol (23)), which showed negligible degradation for 10 hours. The combined operating voltage at MPP was 1.8V which is sufficient to surmount the voltage required in practical PEC cells to drive the unassisted solar water-splitting reaction.

Following the preparation of the planar perovskite solar cells, the next step for the fabrication of an integrated photocathode and photoanode was the design and incorporation of the conducting adhesive barrier, which exhibits three key criteria, (i) low electrical resistance, (ii) physical and chemical resistance to the ingress of corrosive electrolytes, and (iii) compatibility with HaP surface termination (does not degrade any device layers already deposited). In state-of-the-art integrated devices, which uniformly use III-V semiconductors, the ultra-smooth surface terminations (<1 nm roughness) enable the use of many 10 s-of-nm layers of TiO₂ as a barrier. However, the surface roughness and grain size/morphology of perovskite surfaces, as well as their instability of high-temperature deposition techniques such as atomic layer deposition, hinder this strategy for barriers for our halide perovskite system.

Thus, to evaluate the multicomponent conductive adhesive barrier against the key criteria, barrier stability was screened using a drop test, and conductivity was assessed by performing J-V scans of successful candidates connected to metallic films. As shown herein, multicomponent conductive adhesive-barrier systems with a conducting adhesive material were employed to mitigate interface resistance and thick, impermeable, bulk-conductive barrier were successfully evaluated with respect to meeting the above noted criteria. Indeed, separating the design criteria into distinct materials relaxed the constraints on the search for materials, and allowed for the identification of several viable barriers such as pyrolytic graphite sheet and Ti foil, and adhesives such as Ag paste and C ink.

However, when deposited on the top contact of solar cells, the inks led to significant performance losses due to solvent loss. Therefore, a composite polymer-conductive filler adhesive with minimal solvent loss on deposition was prepared, as detailed in accordance with one or more embodiments provided above.

### PSA Preparation

To create a pressure sensitive adhesive (PSA), compatible monomers are copolymerized according to classical methods. A representative protocol follows: for a 10 g batch, the following species were added to a reactor under an inert atmosphere: 4.55 g ethyl acetate+3.55 g isooctyl acrylate+0.05 g methacrylic acid+0.02 g benzoyl peroxide. The reaction vessel was maintained at ˜55° C. and stirred continuously. After a noticeable increase in solution viscosity, the following components were added to the reaction vessel: 0.24 g ethyl acetate+0.12 g methacrylic acid+0.02 g benzoyl peroxide. After 5 hours, 1.45 g ethyl acetate were added. After about 10 h, the reaction was deemed complete, and the product was diluted to a desired viscosity via heptane (between 1-10 mL heptane added per 1 g of polymer product). The PSA was made conductive via addition of silver nanoparticles at concentrations beyond the percolation concentration (ex. 40 mg/mL diluted polymer solution).

### Photoelectrode Fabrication

Graphite sheets with catalysts pre-deposited (see Catalyst Deposition) were adhered to the surface of completed PSCs using conductive adhesive materials to create a fully-encapsulated perovskite photoelectrode. Cu tape was also adhered to scratched-off regions of the same FTO chip to allow for connection to the potentiostat. The non-active area was sealed with epoxy (NOA 68, Norland Optical Adhesives) which was cured under UV light (UVP UVL-21, Analytik Jena US) in air for 20 minutes at approximately a one inch distance. The exposed catalyst area was then measured by a calibrated imager which converted image pixels to real geometric area with high fidelity; broadly, the devices had either a lesser or equal geometric catalyst area relative to their photoabsorber area, and current density data are reported normalized to photoabsorber area. The completed photoelectrode was then adhered to the side wall of the 3D-printed CSTR using a small quantity of polyurethane and allowed to dry for at least 6 hours in air before measurement.

Briefly, a CSTR was designed for simple 3-electrode PEC measurements which was modified for 2-electrode and bias-free measurements and gas collection. In the 3-electrode case, a cube shape with rounded internal edges was used to facilitate flow and minimize contamination between experiments. The reactor had a square base with side length 3.8 cm, 4.0 cm height and 0.2 cm wall thickness. Two holes were also added along the center top side of the reactor with a diameter of 0.8 cm and 1.0 cm to insert working and reference electrodes into electrolyte. Two smokestacks with an internal diameter of 0.125 inches were included on the top corners for product gas inlet and outlet. To minimize losses from incident sunlight, the interfaces were decoupled for light absorption and electrocatalysis. The reactor was designed with a hole centered on a side wall (1.0 cm diameter), using the wall as an adhesion surface to create a seal to which the photoelectrode was adhered.

A dual extruder capable of switching between polypropylene and a dissolvable support material was important to build a foundation for the top layers of the reactor. In this case, PVA (polyvinyl alcohol) was the support material. Unfortunately, the smooth surface of polypropylene (PP) makes adhesion of the first layer of PVA difficult. If not layered correctly, PVA easily compacts on the extruder nozzle which can cause expensive damage and a ruined print. An alternative is a detachable lid which can be printed separately and additionally allows facile cleaning of the reactor. Threaded twist caps with a fitted O-ring offer a compromise between print complexity and tight sealing, and represent the best opportunity for an easily reusable design, while the enclosed print remains the best option for potential product gas removal.

The PEC reactor body had a chemically inert material to prevent degradation due to the presence of extreme pH and high ionic strength media with extended use. 3D printing with PP filament offered a cheap, inert body that created a watertight seal when layered. To adhere PP coming out of extrusion nozzle at 428° F. to the 3D printer bed, the bed temperature was increased to 212° F. (from 150° F.) which stopped the rapid cooling and resolved layer misalignment. A brim added extra material to the first layer to broaden the base of the print and reduce permeability. Both changes contributed to reducing the impact of contractive forces after cooling and provided the following layers a solid base.

For the printing process, an Ultimaker 3 with dual extruders of nozzle size 0.4 mm that produced a 0.48 mm line width when laid on the print bed was used. With these specifications, the layer height was 0.2 mm after material adhesion with a recommended flowrate of 50 mm/s and extruded at 428° F. Recommended heuristics indicated that the extrusion flowrate should stay between 90% and 110% to reduce the chance of layer misalignment. The Ultimaker 3 is programmed with pre-determined settings for printer bed temperature, extruder temperature and infill density for all compatible filaments, and unless otherwise specified default settings were used.

### Catalyst Deposition

Catalysts were deposited on the graphite sheet through sputtering using conventional ink-based methods in which catalyst nanoparticles were suspended in absolute ethanol with 10 microliters of commercial Nafion solution (Sigma) per milliliter of solvent. The available options for catalyst concentrations, identities, and deposition techniques is limited only by the barrier's properties, so sputtering, electrodeposition, hydrothermal, and other methods are facilely possible to deposit precious metal as well as non-precious metal catalysts with high degrees of freedom relative to conventional PECs.

The degree of tack (stickiness) of the composite was adjusted to achieve good physical adhesion without compromising on conductivity.

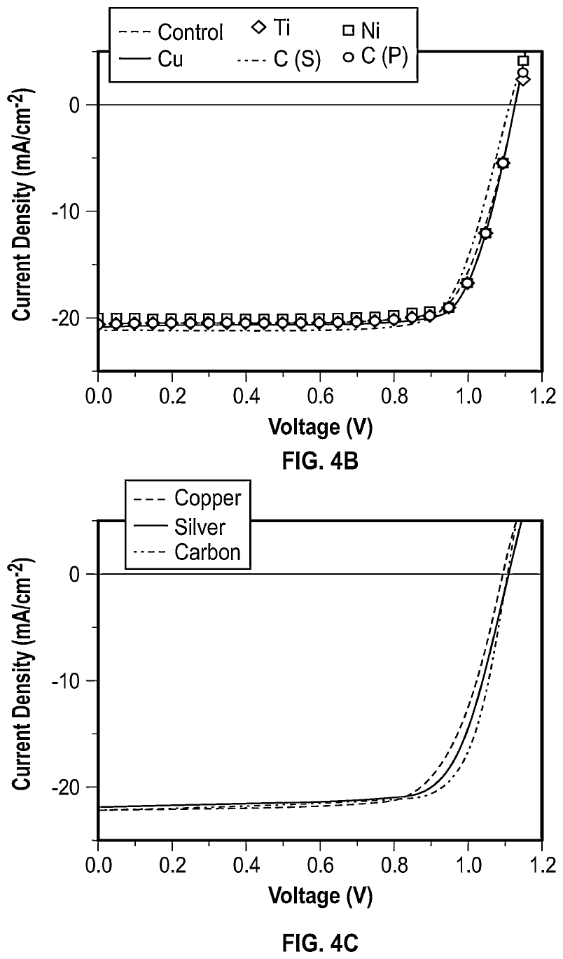

FIGS. 4A-4C show J-V curves of various perovskite solar cells. FIG. 4A shows comparisons of photovoltaic J-V curves under 1-Sun illumination of exemplary perovskite solar cells without (Control) and with various bilayer barriers. Commercial Ag paste and C paste capped with graphite were shown to reduce all figures of merit substantially, while a CAB composed as described herein introduces no losses. FIG. 4B shows photovoltaic J-V curves under 1-Sun illumination of perovskite solar cells using the disclosed CAB with different metallic barriers (i.e., Cu, Ti, graphite from Sigma, graphite from Panasonic, and Ni) demonstrating the versatility of the disclosed CAB with different metallic barriers. FIG. 4C shows photovoltaic J-V curves under 1-Sun illumination of representative perovskite solar cells using only graphite barriers and varying the material used in the conductive filler in the adhesive (Cu, Ag, C). Similarly, performance was maintained for all conductive fillers tested.

Table 1, below, shows the relevant performance data for the J-V curves shown in FIGS. 4A-4C.

TABLE 1

| Sample | | | | |
|---|---|---|---|---|
| (conductive | | | | |
| barrier) | PCE | Voc | Jsc | FF |
| Conrol | 18.0 | 1.13 | 20.72 | 0.77 |
| Ti | 18.1 | 1.12 | 20.76 | 0.78 |
| Cu | 18.4 | 1.12 | 20.87 | 0.79 |
| C (panasonic) | 18.1 | 1.13 | 20.53 | 0.78 |
| Ni | 17.9 | 1.12 | 20.04 | 0.80 |
| C (Sigma) | 18.0 | 1.11 | 21.09 | 0.77 |
| Sample | | | | |
| (conductive | | | | |
| adhesive) | PCE | Voc | Jsc | FF |
| Cu | 17.4 | 1.11 | 21.99 | 0.72 |
| Ag | 18.0 | 1.13 | 21.88 | 0.73 |
| C | 18.4 | 1.13 | 22.15 | 0.74 |

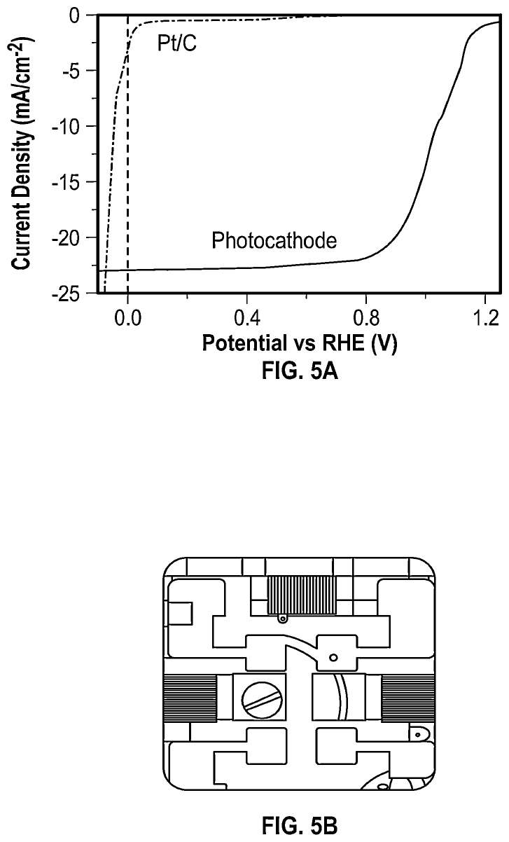

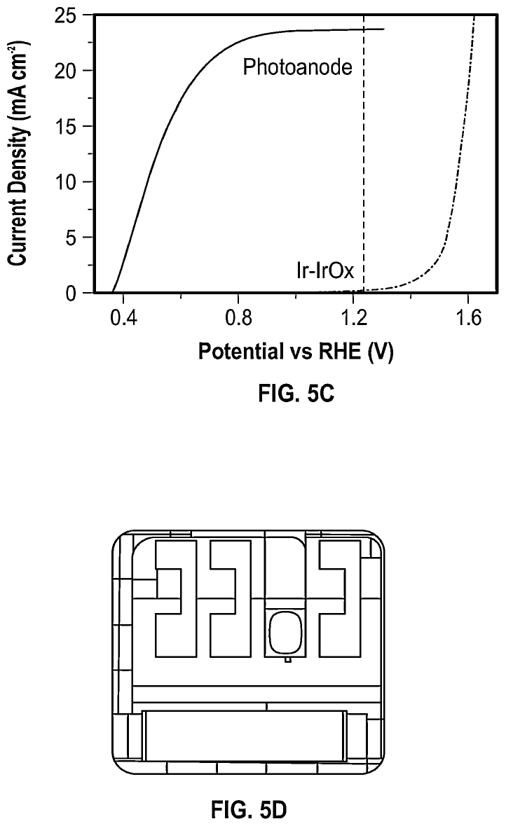

The multifunctionality of the multicomponent conductive adhesive barrier was demonstrated by executing a photocathode for HER using sputtered or ink-based Pt as a catalyst and a photoanode for OER using sputtered or ink-based Ir as a catalyst. The J-V curve data is shown in FIGS. 5A and 5C. The J-V curve in FIG. 5A shows a comparison of photocathode (right trace) and electrocatalyst-only (left trace) J-V curves, with FIG. 5B showing visual image of photocathode surface. Photocathode shows figures of merit (short-circuit current, open-circuit voltage, fill factor) similar to parent p-i-n solar cell, with some losses that can clearly be related to catalysts. FIG. 4C shows a comparison photoanode (left trace) and electrocatalyst-only (right trace) J-V curves, with FIG. 5D showing photoanode surface. Photoanode shows figures of merit similar to parent n-i-p solar cell, with some losses that can be clearly related to catalysts.

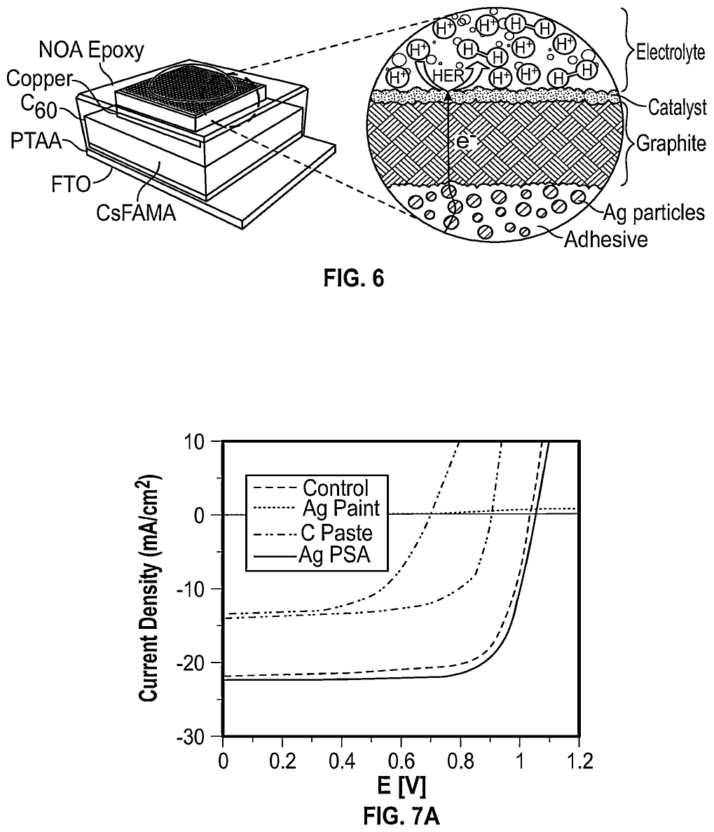

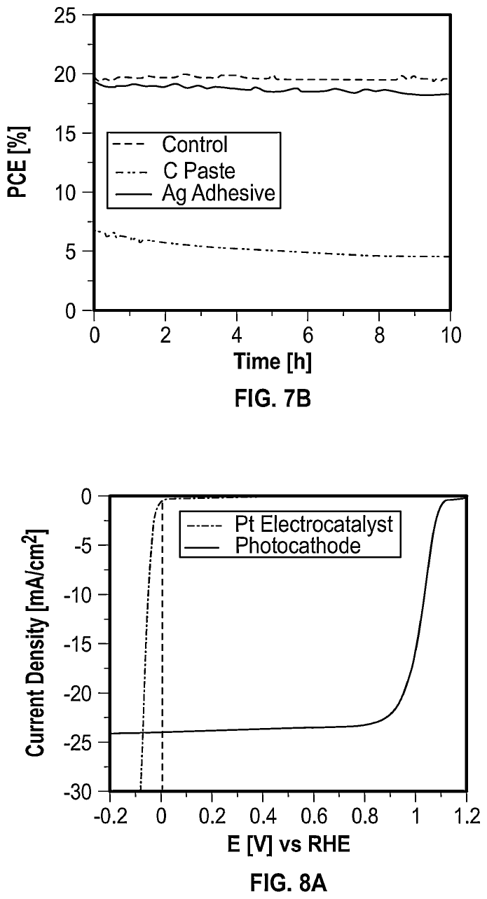

FIG. 6 shows the fabricated photovoltaic devices and the different components of the protective barrier required to achieve low resistance electrical contact and protection. The J-V performance of solar cells was measured before and after attaching the multicomponent CAB layers. FIGS. 7A and 7B show that for the CAB composed of the Ag-doped PSA, low-outgassing composite and a graphite sheet barrier, the J-V curve remains almost identical to the ones without the barrier and is superior to other ink-based CABs in terms of efficiency and stability. The CAB using the disclosed composite adhesive of one or more embodiments offers a unique advantage compared to strategies to fabricate barriers directly onto the photoabsorbers or photovoltaic surfaces. Here, the entire barrier and the catalyst deposition can be performed separately and adhered to the photovoltaic device using a dry transfer process, thus mitigating the risk of degrading the perovskites.

The capability of the multicomponent CAB to create a robust physical barrier without introducing new degradation mechanisms to the cell and with minimal loss to photoconversion efficiency provides the capability to transform high-efficiency photovoltaic s into high-efficiency integrated photoelectrodes.

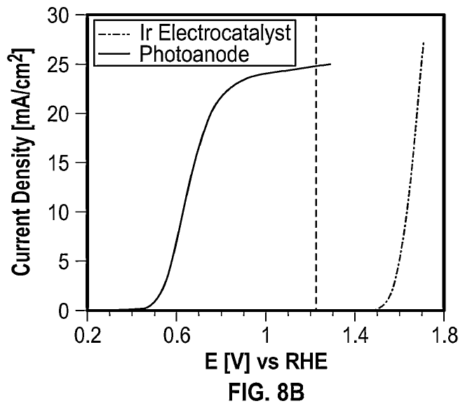

Although the photovoltaic-CAB system is intrinsically capable of operation as a photoelectrode in the water, the catalytic activity of graphite and most other inert conductive barriers (e.g., Ti, Cu, etc.) for HER and OER is low. Accordingly, catalysts were deposited with final areal concentrations of 0.5 mg/cm² of 20 wt % Pt/C (Sigma) and 1 mg/cm² of IrOₓ, nanoparticles synthesized in-house. .FIG. 8A shows the J-V response of the photocathode in 3-electrode mode from open-circuit to−0.2V vs RHE at a rate of 10 mV/s on the CAB with Pt and the PV-CAB with Pt in 0.5M H₂SO₄ with 1-Sun illumination. An overpotential of 70 mV at 20 mA/cm² was measured for the catalyst-only control, whereas the illuminated photocathode showed an anodic shift of the onset of about 1.1V and a current density of about 22 mA/cm² at 0V vs RHE. The shift was consistent with the measured open-circuit voltage and the current density of the parent p-i-n photovoltaic device as shown in FIG. 6. More importantly, the shape of the curve (the “fill factor” of the photocathode's J-V curve) remained almost identical to the curve observed for the parent photovoltaic implying a near-perfect preservation of photovoltaic efficiency. To quantify the conversion efficiency of the half-cell, the photocathode efficiency was calculated, which is the product of the voltage exceeding the standard reduction potential of the half reaction (0V vs RHE for HER) and the current density at the maximum power point and found it to be 18.6% in the champion device. These measurements clearly show that the CAB-Pt interface can almost perfectly translate the photovoltaic efficiency to drive the HER reaction due to low electronic transport resistance and catalyst overpotential.

Similar J-V measurements were performed on the CAB with Ir-based catalyst and the PV-CAB with the same catalyst from open-circuit to +1.3V vs RHE in 0.5M H₂SO₄ (FIG. 8B). Even with precious metal catalysts, the sluggish kinetics of the oxygen evolution reaction (OER) resulted in a high overpotential of 370 mV at 20 mA/cm² for the CAB—Ir system. The illuminated photoanode showed a cathodic shift of onset potential of about 1.1V, again consistent with the parent photovoltaic's V_{OC}, and showed a similarly high fill factor. The HCE of the device was 11.3%, which is lower than the parent photovoltaic efficiency which is due to the high OER catalyst overpotential and not series resistance or cell damage added by the CAB. The data shown in FIGS. 8A and 8B is similar to the data described above with reference to FIGS. 5A and 5B, but was obtained on a different device.

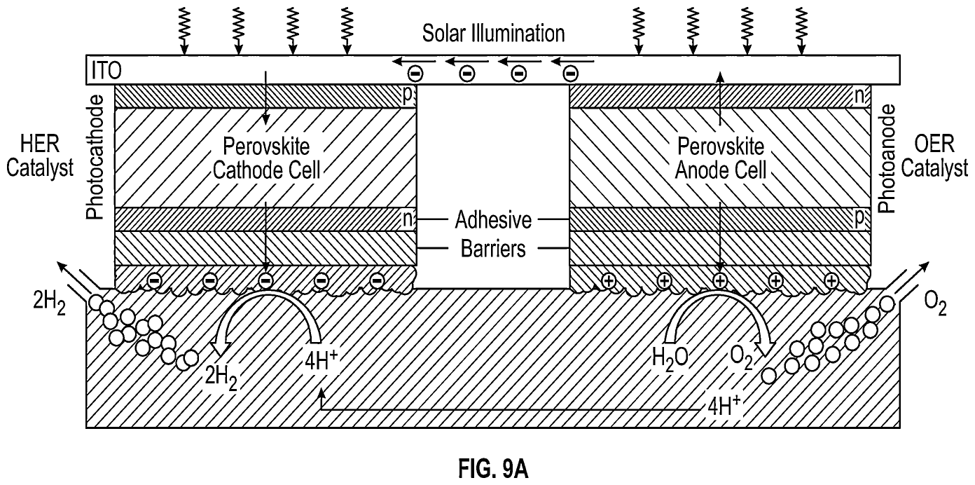

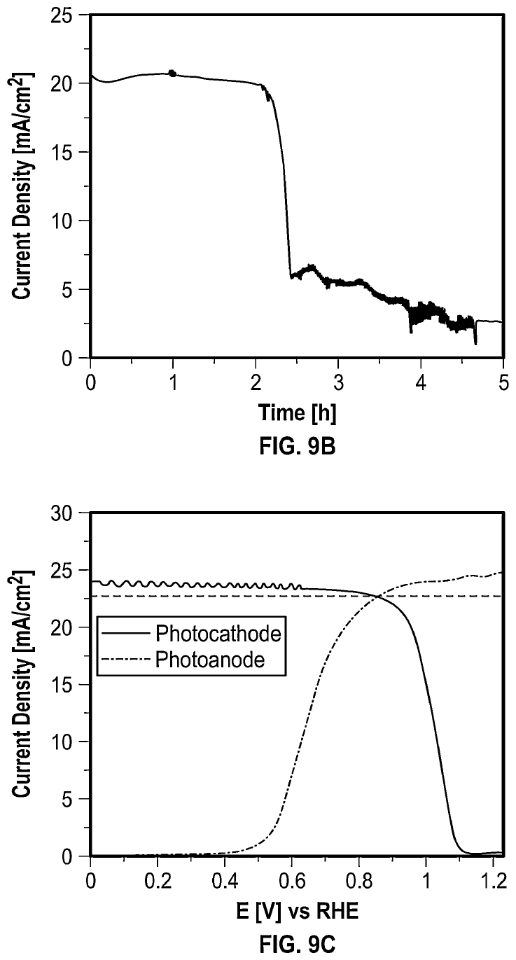

After demonstrating that the PSA-barrier is effective in protecting the perovskites without decreasing their performance, the photocathode and photoanode were connected in series to drive an unassisted water-splitting reaction. A simple 3D printed polypropylene semi-batch reactor was designed with two holes in the side walls for photoelectrodes, and gas inlet and outlet lines for inert gas flow. Multicomponent CAB and catalyst layers were deposited over the contacts of p-i-n and n-i-p solar cells, and encapsulated the rest of the devices with epoxy, and then adhered them to the sidewall holes of the reactor. The integrated HaP-PEs were then illuminated with 1-Sun AM 1.5 G radiation and executed unassisted solar water-splitting. FIG. 9A shows a schematic of the system under study and FIG. 9B shows the time-dependent current density for bias-free water-splitting.

The intersection of the individual photoelectrode J-V curves plotted with absolute current density gives the anticipated bias-free current density, which were found to be about 22.1 mA/cm² (FIG. 9C). However, operating conditions for 3-electrode measurements do not match those of bias-free operation, and the photocurrent density achieved was about 21.8 mA/cm²(FIG. 9A). Assuming a modest Faradaic efficiency of unity for HER with a Pt catalyst in 0.5M H₂SO₄, which is a well-studied system, and accounting for the area contributions of two separate photoabsorbers, this current density corresponds to a solar-to-hydrogen (STH) efficiency of up to 13.4%, as calculated using the below formula.

$$STH = \frac{1.23 V \times {J}_{op} \times FE}{{P}_{sunlight}}$$

This is the first integrated photoelectrode-type system using halide perovskite, and one of only a handful of non-III-V integrated systems, to achieve>10% STH, which is generally regarded as a commercially relevant efficiency. The device maintained a high current density for 2 hours before abruptly degrading, likely due to the OER catalyst's demonstrated instability. This STH is >2×that of any published integrated perovskite photoelectrode devices, and with a state-of-the-art stability, fully enabled by the CAB.

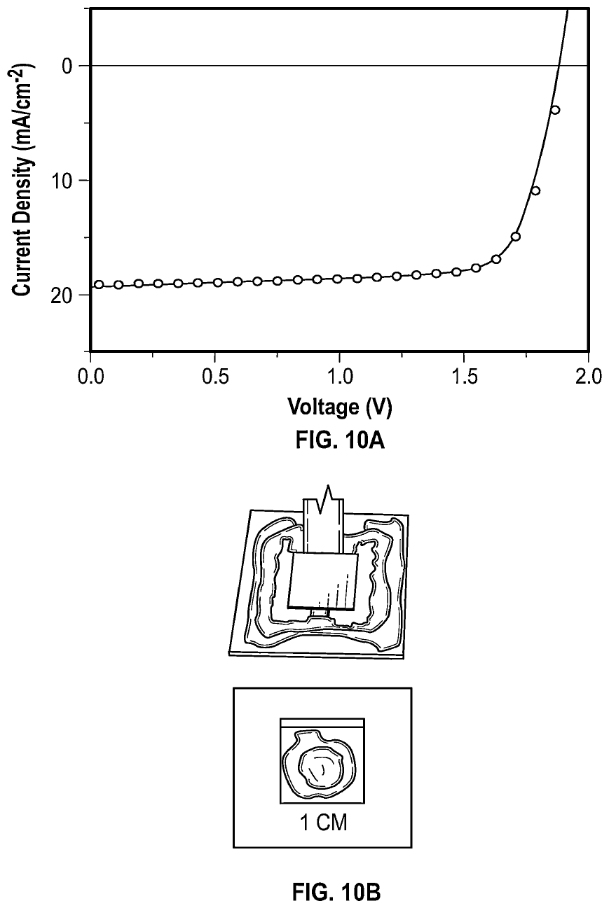

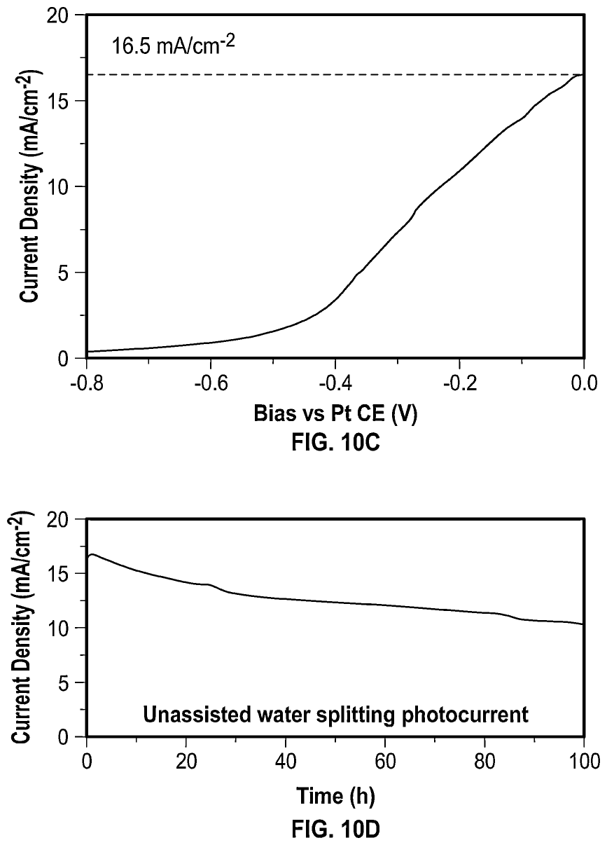

To demonstrate the functionality of the CAB on different photoabsorbers, we also tested its ability to convert silicon-perovskite solar cells into photoanodes for unassisted solar water-splitting, the details of which are shown in FIGS. 10A-10D. Silicon-perovskite solar cells with 1 cm² area achieved a PCE of 27.7%, V_{OC} 1.90 V, J_{SC} 19.2 mA/cm², and FF of 0.76 under 1-Sun illumination, as provided in FIG. 10A. We attached the same CAB and IrOₓ catalyst discussed previously to the Si face of the photovoltaic, encapsulated the non-active area in epoxy, and adhered the device to the reactor as before. Photographs showing the back (top image) and front (bottom image) are shown in FIG. 10B. J-V characteristics of the photoanode in 2-electrode mode with a Pt foil counterelectrode (CE) gave a current density of 16.5 mA/cm² at 0 V vs the CE, as shown in FIG. 10C. This demonstrates superb agreement with the maximum power point of the photovoltaic less the reaction voltage costs. We allowed the device to operate continuously at short-circuit until its t60 value of 102 hours as shown in FIG. 10D. The peak photocurrent during this test after about 1 hour was 16.9 mA/cm², originating from improvements through heat harvesting discussed below. We also provide evidence that the degradation originated from both the photovoltaic and catalysts' independent degradation, rather from effects caused by the integration with the CAB.

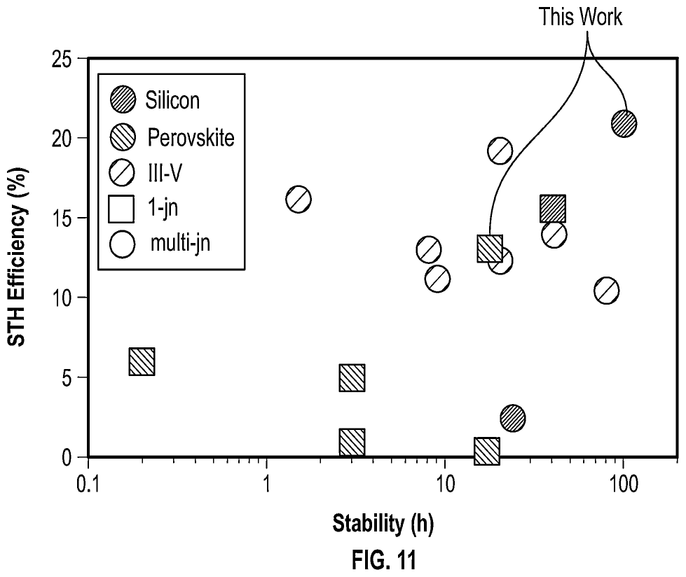

In order to compart to state-of-the-art technologies, the STH efficiency of data provided herein was plotted against leading technologies. The comparison plot is shown in FIG. 11. As shown, the present work is comparable to, or better than, leading technologies.

Perovskite Solar Cell Characterization

The solar cell current-voltage characteristics were measured using a Keithley 2400 Source meter at a rate of 0.05V/s from 0-1.2V (Forward scan) and 1.2-0V (Reverse Scan). AM1.5 G (100 mW/cm²) illumination was provided by 450 W Xe lamp solar simulator (Oriel LCS 100). The simulated solar illumination intensity was calibrated with a Newport Si reference cell. The external quantum efficiency was measured using a QUANTX 300 EQE system from 320 nm-820 nm wavelength with a step of 2 nm and a chopper frequency of 40 Hz.

The solar cells were encapsulated in UV-cured epoxy (Norland Optical Adhesive 68) and the stability was measured using maximum power point (MPP) tracking under simulated AM 1.5 G (100 mW/cm²) using the above solar simulator.

Waste Heat Recovery

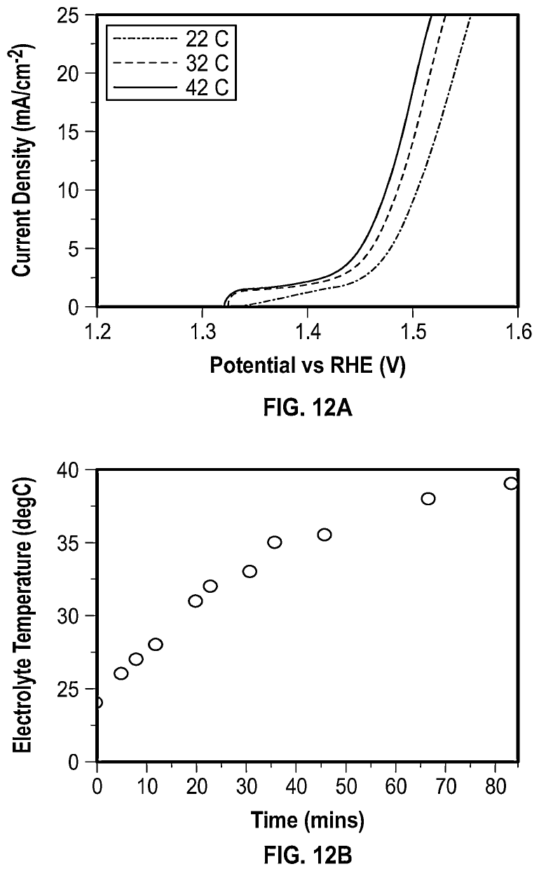

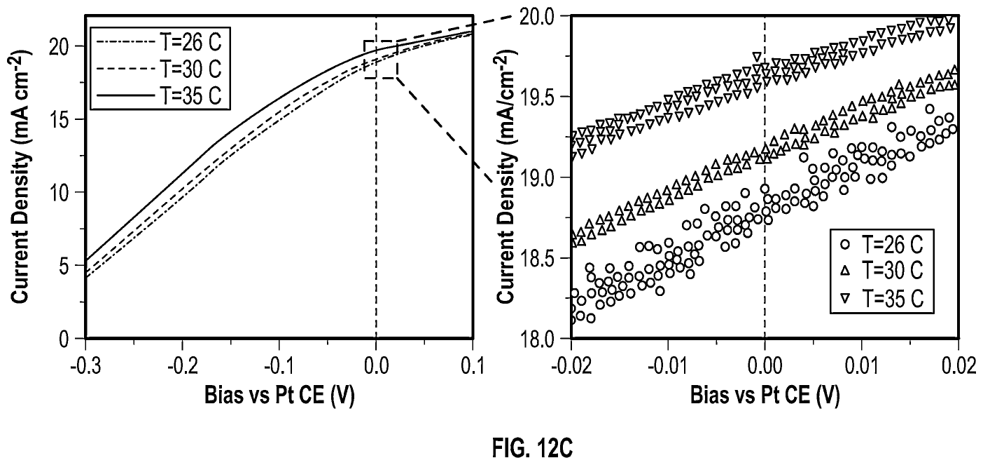

The CAB described herein was incorporated into an integrated photoelectrode (I-PEC) to test waste heat recovery. The activity of a model oxidation electrocatalyst (here, IrOₓ) was observed at varied temperatures, as shown in FIG. 12A. For operation at a current density of 15 mA/cm², it was observed that increasing the operating temperature from 22° C. to 32° C. or 42° C. yielded an overpotential savings of 11.5 and 22.1 mV, respectively.

Additional properties were observed for a photoanode attached to a 3D printed stirred tank reactor. At an incident solar flux of 100 mW/cm² (AM 1.5 G 1 sun illumination) the electrolyte temperature was observed to increase from ambient 23° C. to 40° C. within 90 minutes of continuous operation, as shown in FIG. 12B. The observed decreases in overpotential requirements significantly increases the I-PEC operating current density—hydrogen production rate—when the device is not in its photocurrent limited regime.

This effect was monitored for a photoanode consisting of a silicon-perovskite and the aforementioned IrOₓ electrocatalyst. It was observed that as the electrolyte temperature increased from ambient to 40° C., the photoelectrode performance also improved. The operating point of a photoelectrode, absent of external bias, is 0 volts vs the counter electrode. Observing the integrated photoelectrode curve as a function time, it can be determined that the operating current density increases as the electrocatalyst microenvironment heats up, as shown in FIG. 12C. Thermal integration via use of the CAB enables an increase in solar to hydrogen efficiency of 1 percentage point. Furthermore, use of thermal integration in integrated photoelectrodes potentially decreases the balance of systems costs associated with cooling the photovoltaic in photovoltaic-electrolyzer systems.

What is claimed is:

1. A multicomponent conductive adhesive barrier for a photoelectrode structure, the multicomponent conductive adhesive barrier comprising:
an adhesive layer, wherein the adhesive layers comprises a doped pressure-sensitive adhesive (PSA); and
a conductive barrier layer, wherein the conductive barrier layer is a carbon or metal-based material.

2. The multicomponent conductive adhesive barrier of claim 1, wherein the conductive barrier layer further comprises an electrocatalyst deposited on its surface.

3. The multicomponent conductive adhesive barrier of claim 1, wherein the adhesive layer is doped with silver (Ag) nanoparticles, copper (Cu) nanoparticles, or carbon black beyond a percolation concentration.

4. The multicomponent conductive adhesive barrier of claim 1, wherein both the adhesive layer and the conductive barrier layer have a resistance of less than 1 ohm.

5. The multicomponent conductive adhesive barrier of claim 1, wherein the conductive barrier layer is at least one selected from amorphous carbon, graphite, and graphene.

6. The multicomponent conductive adhesive barrier of claim 1, wherein the conductive barrier layer is metallic sheet selected from stainless steel, nickel (Ni), aluminum (Al), copper (Cu), tantalum (Ta), niobium (Nb), and titanium (Ti).

7. A photoelectrode structure comprising:
a substrate;
a photoabsorbing layer;
a multicomponent conductive adhesive barrier; and
an electrocatalyst,
wherein the multicomponent conductive adhesive barrier comprises:
an adhesive layer, wherein the adhesive layers comprises a doped pressure-sensitive adhesive (PSA); and
a conductive barrier layer, wherein the conductive barrier layer is a carbon or metal-based material.

8. The photoelectrode structure of claim 7, wherein the adhesive layer of the multicomponent barrier is in contact with both the conductive barrier layer and the photoabsorbing layer such that it separates the two.

9. The photoelectrode structure of claim 8, wherein the electrocatalyst is deposited onto a surface of the conductive barrier layer, where the surface is opposite of the surface that is in contact with the adhesive layer.

10. The photoelectrode structure of claim 7, wherein the photoabsorbing layer comprises a halide perovskite.

11. The photoelectrode structure of claim 7, wherein the photoelectrode structure is a photocathode, and where the electrocatalyst is selected from the group consisting of Pt, NiMo, NiMoZn, MoS₂, of Mo₃S₄.

12. The photoelectrode structure of claim 7, wherein the photoelectrode structure is a photoanode, and the electrocatalyst is selected from the group consisting of Ir, IrO₂, Ru, RuO₂, Co₃O₄, or Co-Pi.

13. The photoelectrode structure of claim 7, wherein the conductive barrier layer of the multicomponent barrier has a thickness of 10 μm to about 100 μm.

14. A method for fabricating a photoelectrode structure comprising:
applying a photoabsorbing layer to a substrate;
preparing an adhesive layer, wherein the adhesive layers comprises a doped pressure-sensitive adhesive (PSA); and
forming a multicomponent conductive adhesive barrier by applying a conductive barrier layer to the adhesive layer.

15. The method of claim 14, wherein the forming of the multicomponent conductive adhesive barrier is completed after applying the adhesive layer to the to the photoabsorbing layer.

16. The method of claim 14, wherein the forming of the multicomponent conductive adhesive barrier is completed before applying the adhesive layer to the to the photoabsorbing layer.

17. The method of claim 14, wherein an electrocatalyst is deposited onto a surface of the conductive adhesive barrier either before or after the forming of the multicomponent conductive adhesive barrier.

18. The method of claim 14, wherein the multicomponent conductive adhesive barrier is removed from the photoabsorbing layer by peeling it off.

19. The method of claim 18, wherein the multicomponent conductive adhesive barrier is removed and replaced.

20. The method of claim 18, wherein the multicomponent conductive adhesive barrier is removed and recycled by applying it to another photoelectrode.
